(19) United States
(12) Patent Application Publication
(10) Pub. No.: US 2025/0004338 A1
(43) Pub. Date: Jan. 2, 2025

(54) ELECTRO-OPTICAL DEVICE AND ELECTRONIC DEVICE

(71) Applicant: SEIKO EPSON CORPORATION, Tokyo (JP)

(72) Inventor: Daisuke MIYAWAKI, CHITOSE-SHI (JP)

(73) Assignee: SEIKO EPSON CORPORATION, Tokyo (JP)

(21) Appl. No.: 18/757,429

(22) Filed: Jun. 27, 2024

(30) Foreign Application Priority Data
Jun. 29, 2023 (JP) 2023-106807

(51) Int. Cl. G02F 1/1362; G02F 1/1335; G02F 1/1368; G03B 21/00; H01L 27/12; H01L 29/786

(52) U.S. Cl. CPC G02F 1/136286; G02F 1/133526; G02F 1/1368; H01L 27/1222; H01L 27/124; H01L 27/1255; H01L 29/78621; H01L 29/78633; H01L 29/78675; G03B 21/006

(57) ABSTRACT

Provided is an electro-optical device including a transistor, a pixel electrode provided on a light incidence side of the transistor, a lens layer provided in a layer between the transistor and the pixel electrode, and a relay layer serving as a first relay layer that is provided in a layer between the lens layer and the pixel electrode and electrically connected to the pixel electrode, wherein the relay layer includes WSi on the pixel electrode side.

The present application is based on, and claims priority from JP Application Serial Number 2023-106807, filed Jun. 29, 2023, the disclosure of which is hereby incorporated by reference herein in its entirety.

### BACKGROUND

### 1. Technical Field

The present disclosure relates to an electro-optical device and an electronic device including the electro-optical device.

### 2. Related Art

As a related electro-optical device, for example, one described in JP-A-2021-167884 is known. JP-A-2021-167884 describes a liquid crystal device including a pixel electrode provided on a light incidence side of a substrate body of an element substrate, a transistor provided between the pixel electrode and the substrate body, a lens provided between the pixel electrode and the transistor, and a relay electrode provided between the lens and the transistor.

In the liquid crystal device described in JP-A-2021-167884, the lens provided between the pixel electrode and the transistor can guide light traveling to the relay electrode to a light-transmitting region, and thus a bright image can be displayed.

However, when the lens is provided between the pixel electrode and the transistor, it is difficult to electrically connect the pixel electrode to the transistor via a contact hole or the like due to a thickness of the lens, and when the relay electrode is provided to electrically connect the pixel electrode to the transistor, a distance between the lens and the relay electrode is short, and thus it is difficult to guide all of the light traveling to the relay electrode to the light-transmitting region.

Accordingly, there is a problem that light hitting the relay electrode increases a temperature of a liquid crystal panel.

### SUMMARY

An electro-optical device according to one aspect of the present application includes a transistor, a pixel electrode provided on a light incidence side of the transistor, a lens layer provided in a layer between the transistor and the pixel electrode, and a first relay layer that is provided in a layer between the lens layer and the pixel electrode and electrically connected to the pixel electrode, wherein the first relay layer includes WSi.

An electro-optical device according to one aspect of the present application includes a data line extending in a first direction, a scanning line extending in a second direction intersecting the first direction, a transistor electrically connected to the data line and the scanning line, a pixel electrode provided on a light incidence side of the transistor, a lens layer provided in a layer between the transistor and the pixel electrode, a first relay layer that is provided in a layer between the lens layer and the pixel electrode and electrically connected to the pixel electrode, and a second relay layer that is provided in a layer between the transistor and the lens layer and electrically connected to the first relay layer, wherein the second relay layer includes a main body portion overlapping the transistor in plan view, a first protruding portion protruding from the main body portion in the first direction, and a second protruding portion protruding from the main body portion in the second direction, and the main body portion, the first protruding portion, and the second protruding portion include WSi on the pixel electrode side.

An electronic device according to one aspect of the present application includes the electro-optical device described above.

### BRIEF DESCRIPTION OF THE DRAWINGS

FIG. 1 is a plan view of an electro-optical device according to Embodiment 1.

FIG. 2 is a cross-sectional view of the electro-optical device along line II-II in FIG. 1.

FIG. 3 is an equivalent circuit diagram showing an electrical configuration of an element substrate.

FIG. 4 is an explanatory diagram showing a cross-sectional structure of a display region of the element substrate.

FIG. 5 is a plan view showing a part of the display region of the element substrate.

FIG. 6 is an explanatory diagram showing a cross-sectional structure along line VI-VI in FIG. 5.

FIG. 7 is an explanatory diagram showing a cross-sectional structure according to Modified Example 1.

FIG. 8 is an explanatory diagram showing a cross-sectional structure according to Modified Example 2.

FIG. 9 is an explanatory diagram showing a cross-sectional structure according to Modification Example 3.

FIG. 10 is an explanatory diagram showing a cross-sectional structure according to Modification Example 4.

FIG. 11 is a schematic diagram showing an example of an electronic device according to Embodiment 2.

### DESCRIPTION OF EMBODIMENTS

Embodiments of the present disclosure will be described below with reference to the drawings.

Also, in each figure below, in order to make each constituent element easier to see, dimensions of some constituent elements may be shown on different scales.

In addition, in the following description, for convenience of explanation, an X axis, a Y axis, and a Z axis, which are orthogonal to each other, will be used as appropriate. Further, one direction along the X axis will be referred to as an X1 direction, and a direction opposite to the X1 direction will be referred to as an X2 direction. Likewise, one direction along the Y axis will be referred to as an Y1 direction, and a direction opposite to the Y1 direction will be referred to as an Y2 direction One direction along the Z axis will be referred to as an Z1 direction, and a direction opposite to the Z1 direction will be referred to as an Z2 direction. Also, in the following description, a view in the Z1 direction or the Z2 direction will be referred to as a “plan view”, and a view in a direction perpendicular to a cross-section including the Z axis will be referred to as a “cross-sectional view”.

Further, in the following description, for example, with respect to a substrate, the expression “on a substrate” indicates any one of a case in which an object is disposed on the substrate in contact therewith, a case in which an object is disposed over the substrate via another structure, and a case in which an object is disposed on the substrate partially in contact therewith and partially via another structure. In addition, “upper surface of a substrate” indicates a surface of the substrate on the Z1 direction side.

### 1. Embodiment 1

In the embodiment, an example of a liquid crystal device will be described as an electro-optical device.

The liquid crystal device is an active drive type transmissive liquid crystal device including a thin film transistor (TFT) as a switching element for each pixel. This liquid crystal device is used, for example, as a light modulation device in a projection type display device, which will be described later.

### 1.1. Overview of Structure of Liquid Crystal Device

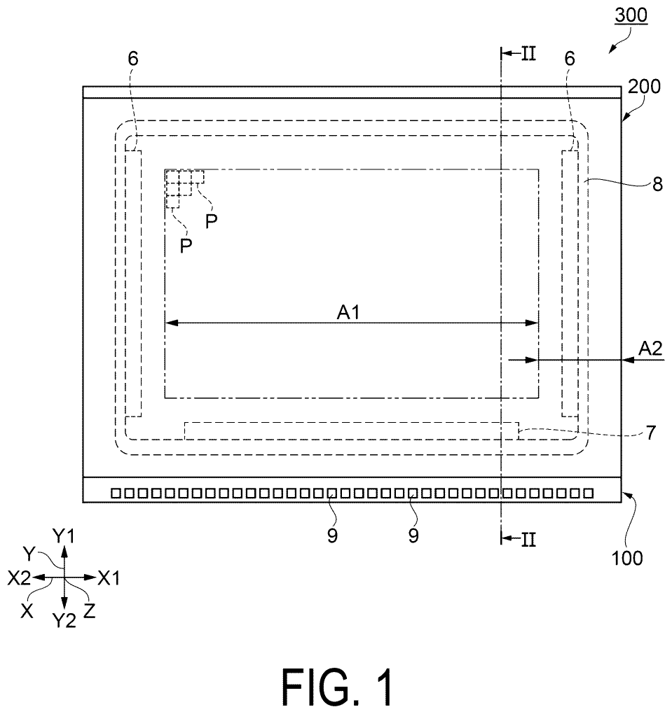

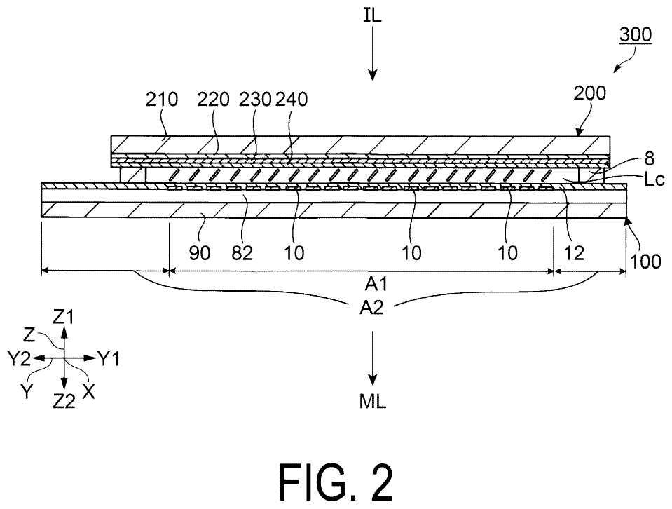

A structure of a liquid crystal device 300 according to the embodiment will be described with reference to FIGS. 1 and 2. FIG. 1 is a plan view of the liquid crystal device 300. FIG. 2 shows a schematic cross-sectional configuration of the liquid crystal device 300 along line II-II in FIG. 1.

As shown in FIGS. 1 and 2, the liquid crystal device 300 includes an element substrate 100 having light transmittancy, a counter substrate 200 having light transmittancy, a sealing member 8 provided in a frame shape, and a liquid crystal layer Lc. In addition, “light transmittancy” means transmittance to visible light and preferably indicates that a transmittance to visible light is 50% or more.

The liquid crystal device 300 includes a display region A1 for displaying an image, and a peripheral region A2 located outside the display region A1 in plan view.

A plurality of pixels P arranged in a matrix are provided in the display region A1. Also, although a shape of the liquid crystal device 300 shown in FIG. 1 is a quadrangular shape, other shapes such as a circular shape may also be adopted.

As shown in FIG. 2, the element substrate 100 and the counter substrate 200 are disposed with the liquid crystal layer Lc interposed therebetween.

In the embodiment, the counter substrate 200 is disposed on a light incidence side of the liquid crystal layer Lc, and the element substrate 100 is disposed on a light emission side of the liquid crystal layer Lc. Incident light IL incident on the counter substrate 200 is modulated by the liquid crystal layer Lc and emitted from the element substrate 100 as modulated light ML.

The element substrate 100 includes a base material 90, a plurality of interlayer insulating layers including an interlayer insulating layer 82, a pixel electrode 10, and an alignment film 12. In addition, although not shown, a lens layer 34, which will be described later, is provided between the pixel electrode 10 and the interlayer insulating layer 82.

The base material 90 is a flat plate having light transmittancy and insulation properties. The base material 90 is a glass substrate or a quartz substrate, for example. A transistor, which will be described later, is disposed between the plurality of interlayer insulating layers.

The pixel electrode 10 has light transmittancy. The pixel electrode 10 is made of a transparent conductive material such as indium tin oxide (ITO), indium zinc oxide (IZO), or fluorine-doped tin oxide (FTO), for example. A thickness direction of the pixel electrode 10 coincides with the Z1 direction or the Z2 direction.

The alignment film 12 has light transmittancy and insulation properties. The alignment film 12 aligns liquid crystal molecules of the liquid crystal layer Lc. Examples of a material of the alignment film 12 include silicon oxide (SiO₂) and polyimide.

The counter substrate 200 includes a base material 210, an insulating layer 220, a common electrode 230, and an alignment film 240.

The base material 210 is a flat plate having light transmittancy and insulation properties. The base material 210 is a glass substrate or a quartz substrate, for example.

The insulating layer 220 has light transmittancy and insulation properties. Examples of a material of the insulating layer 220 include an inorganic material such as silicon oxide.

The common electrode 230 is an electrode disposed to face the plurality of pixel electrodes 10. The common electrode 230 may be referred to as a counter electrode instead. The common electrode 230 includes a transparent conductive material such as ITO, IZO, or FTO, for example. The common electrode 230 and the pixel electrode 10 apply an electric field to the liquid crystal layer Lc.

The alignment film 240 has light transmittancy and insulation properties.

The sealing member 8 is disposed between the element substrate 100 and the counter substrate 200. The sealing member 8 is formed with, for example, an adhesive containing various curable resins such as an epoxy resin. The sealing member 8 may include a gap member made of an inorganic material such as glass.

The liquid crystal layer Lc is disposed in a region surrounded by the element substrate 100, the counter substrate 200 and the sealing member 8. The liquid crystal layer Lc is an electro-optical layer whose optical characteristics change in accordance with the electric field generated by the pixel electrode 10 and the common electrode 230. The liquid crystal layer Lc contains the liquid crystal molecules having positive or negative dielectric anisotropy. The alignment of the liquid crystal molecules changes in accordance with the electric field applied to the liquid crystal layer Lc. The liquid crystal layer Lc modulates the incident light IL in accordance with the applied electric field.

As shown in FIG. 1, a plurality of scanning line drive circuits 6, a data line drive circuit 7, and external terminals 9 are disposed in the peripheral region A2 of the element substrate 100.

The external terminals 9 are mounting terminals on which an external coupling line such as a flexible printed circuit (FPC) (not shown) is mounted. Various signals including an image signal, a synchronization signal, an inspection signal, a common potential, a power supply potential, and the like are supplied to the external terminals 9 from the outside via the external coupling line.

### 1.2. Electrical Configuration of Element Substrate

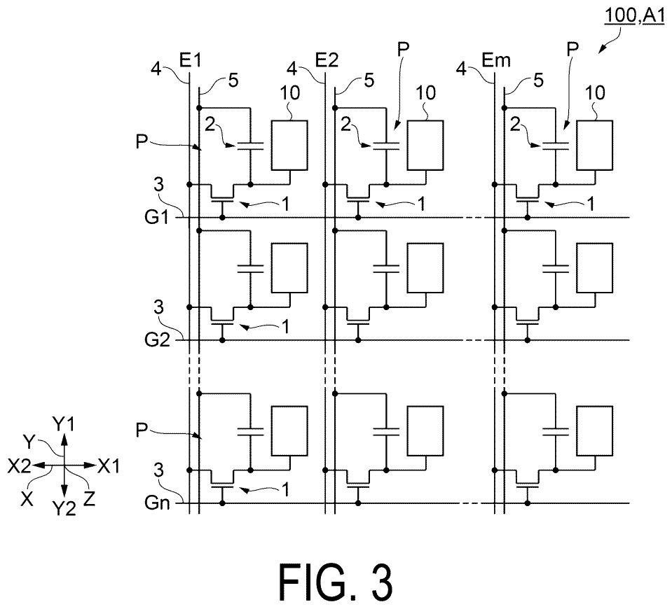

FIG. 3 is an equivalent circuit diagram showing an electrical configuration of the element substrate 100.

As shown in FIG. 3, a plurality of transistors 1, m data lines 4, n scanning lines 3, and m capacitance lines 5 are provided in the display region A1 of the element substrate 100. n and m are each integers of 2 or more. The transistors 1 are disposed at positions corresponding to each intersection of the n scanning lines 3 and the m data lines 4.

The data lines 4 extend in the Y1 direction, and the m data lines 4 are arranged at equal intervals in the X1 direction. The data lines 4 are electrically connected to source regions of the transistors 1. The data lines 4 are electrically connected to the data line drive circuit 7 shown in FIG. 1.

The data line drive circuit 7 supplies image signals E1, E2, . . . , and Em to 1 to m data lines 4.

The scanning lines 3 extend in the X1 direction, and the n scanning lines 3 are arranged at equal intervals in the Y1 direction. The scanning lines 3 are electrically connected to gate electrodes of the transistors 1. The scanning lines 3 are electrically connected to the scanning line drive circuits 6 shown in FIG. 1.

The scanning line drive circuits 6 supply scanning signals G1, G2, . . . , and Gn to 1 to n scanning lines 3 line-sequentially.

The m data lines 4 and the n scanning lines 3 are electrically insulated from each other and disposed in a lattice shape in plan view. A region surrounded by two adjacent scanning lines 3 and two adjacent data lines 4 corresponds to a pixel P. Also, the Y1 direction is an example of a first direction, and the X1 direction is an example of a second direction.

The pixel electrodes 10 are provided for each pixel P. The pixel electrodes 10 are electrically connected to drain regions of the transistors 1.

The capacitance lines 5 extend in the Y1 direction, and the m capacitance lines 5 are arranged at equal intervals in the X1 direction. In addition, the capacitance lines 5 are electrically isolated from the data lines 4 and the scanning lines 3 and are disposed at intervals with them. A fixed potential such as a common potential or a ground potential is applied to the capacitance lines 5 via the external terminals 9.

One electrodes of capacitive elements 2 are electrically connected to the capacitance lines 5. The other electrodes of the capacitive elements 2 are electrically connected to the pixel electrodes 10 and hold potentials of the image signals supplied to the pixel electrodes 10.

### 1.3. Overview of Cross-Sectional Structure of Display Region of Element Substrate

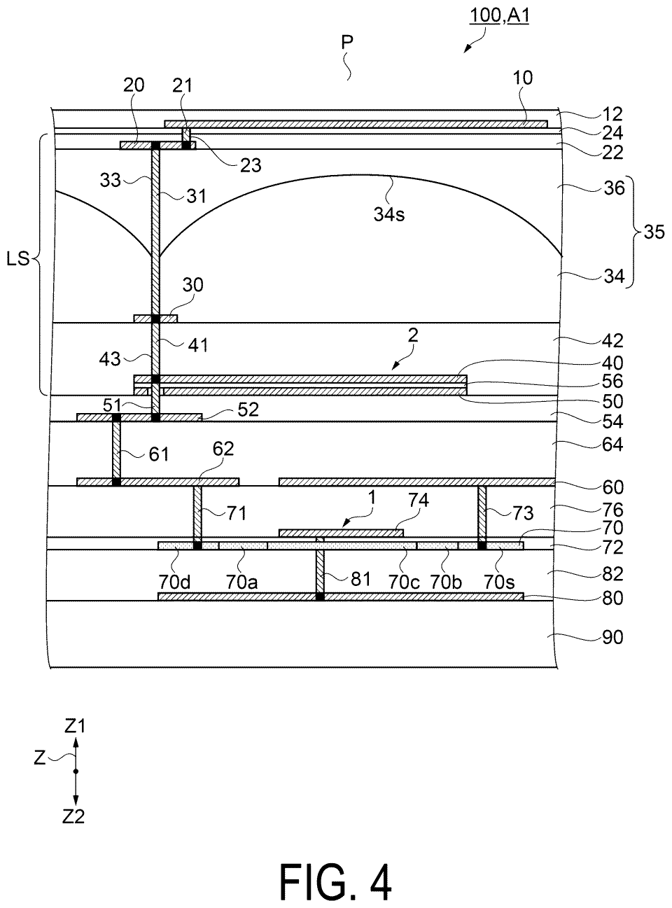

FIG. 4 is an explanatory diagram showing a cross-sectional structure of the display region A1 of the element substrate 100 and shows a lamination relationship and a coupling relationship between layers constituting the pixel P provided in the display region A1.

As shown in FIG. 4, in the display region A1, the element substrate 100 has a structure in which insulating or conductive functional layers or films are laminated on the base material 90.

A light-shielding layer 80 is disposed between the base material 90 and the interlayer insulating layer 82.

The light-shielding layer 80 is made of a conductive material having a light-shielding property. Also, by using a conductive material having a light-shielding property for a conductive functional layer or functional film, the conductive functional layer or functional film can function as a light-shielding layer.

For the conductive material having a light-shielding property, metals such as tungsten (W), titanium (Ti), chromium (Cr), iron (Fe), and aluminum (Al), and metal materials such as metal nitrides and metal silicides can be used. The same applies hereinafter. Also, “light-shielding property” means a shielding property to visible light, preferably indicates that the transmittance to visible light is less than 50%, and more preferably 10% or less.

The light-shielding layer 80 forms a part of the scanning line 3.

The interlayer insulating layer 82 has light transmittancy and insulation properties. The interlayer insulating layer 82 is made of an inorganic material such as silicon oxide (SiO₂), for example. Hereinafter, each interlayer insulating layer is made of the same material as the interlayer insulating layer 82.

The transistor 1 is disposed on the interlayer insulating layer 82.

The transistor 1 includes a semiconductor layer 70 having a lightly doped drain (LDD) structure, a gate electrode 74, and a gate insulating layer 72.

The semiconductor layer 70 includes a drain region 70d, a lightly doped drain (LDD) region 70a, a channel region 70c, an LDD region 70b and a source region 70s.

The semiconductor layer 70 is, for example, polysilicon, and regions other than the channel region 70c are doped with impurities to increase conductivity. Concentrations of impurities in the LDD region 70b and the LDD region 70a are lower than concentrations of impurities in the source region 70s and the drain region 70d.

The gate electrode 74 is provided on the semiconductor layer 70 with the gate insulating layer 72 interposed therebetween. The gate electrode 74 overlaps the channel region 70c of the semiconductor layer 70.

The gate electrode 74 is formed using polysilicon doped with impurities to increase conductivity, for example. Also, the gate electrode 74 may be formed using a conductive material such as a metal, a metal silicide or a metal compound.

The gate insulating layer 72 is made of silicon oxide deposited by, for example, thermal oxidation, a chemical vapor deposition (CVD) method, or the like.

The gate electrode 74 and the light-shielding layer 80 are electrically connected to each other via a contact hole 81. The contact hole 81 penetrates the gate insulating layer 72 and the interlayer insulating layer 82.

An interlayer insulating layer 76 is provided on the transistor 1.

A conductive layer 60 and a relay layer 62 are provided on the interlayer insulating layer 76.

The conductive layer 60 and the relay layer 62 are provided at the same layer and are made of a light-shielding conductive material. The conductive layer 60 and the relay layer 62 preferably have a three-layer structure of titanium nitride, aluminum, and titanium nitride.

The conductive layer 60 forms a part of the data line 4. The conductive layer 60 is electrically connected to the source region 70s of the semiconductor layer 70 via a contact hole 73 penetrating the interlayer insulating layer 76.

The relay layer 62 is electrically connected to the drain region 70d of the semiconductor layer 70 via a contact hole 71 penetrating the interlayer insulating layer 76.

An interlayer insulating layer 64 is provided on the interlayer insulating layer 76, the conductive layer 60, and the relay layer 62.

A relay layer 52 is provided on the interlayer insulating layer 64. The relay layer 52 is made of a light-shielding conductive material.

The relay layer 52 is electrically connected to the relay layer 62 via a contact hole 61 penetrating the interlayer insulating layer 64.

An interlayer insulating layer 54 is provided on the interlayer insulating layer 64 and the relay layer 52.

The capacitive element 2 is provided on the interlayer insulating layer 54.

The capacitive element 2 includes a capacitive electrode 50 configured of a conductive layer, and a capacitive electrode 40 that is an example of a relay layer. The capacitive electrode 50 is provided on the base material 90 side, and the capacitive electrode 40 is provided on the pixel electrode 10 side. In addition, a capacitive insulating film 56 is provided between the capacitive electrode 40 and the capacitive electrode 50. The capacitive electrode 40 and the capacitive electrode 50 are both made of a light-shielding conductive material. The capacitive insulating film 56 is made of a desired dielectric material.

The capacitive electrode 50 forms a part of the capacitance line 5.

The capacitive electrode 40 is electrically connected to the relay layer 52 via a contact hole 51 penetrating the interlayer insulating layer 54. In this manner, the capacitive electrode 40 is electrically connected to the drain region 70d of the transistor 1 and functions as a relay electrode for electrically coupling the transistor 1 to the pixel electrode 10. In addition, an image signal supplied to the pixel electrode 10 is supplied to the capacitive electrode 40, and a fixed potential is supplied to the capacitive electrode 50 from the capacitance line 5, and thus, the capacitive element 2 functions as a storage capacitor.

An optical functional layer LS including the lens layer 34 is provided between the capacitive electrode 40 and the pixel electrode 10.

The optical functional layer LS is provided for inhibiting light loss. Specifically, it adjusts an optical path of passing light such that the passing light that has passed through the pixel electrode 10 is not lost by hitting a functional layer made of a light-shielding conductive material such as the data line 4 or the capacitance line 5.

The optical functional layer LS includes a light-transmitting layer 42, a lens forming layer 35, a light-transmitting layer 22, and a protective layer 24.

The light-transmitting layer 42 is an optical path length adjusting layer that is referred to as a path layer for adjusting an optical path length. The light-transmitting layer 42 is made of an inorganic material such as silicon oxide. An upper surface of the light-transmitting layer 42 is planarized by CMP or the like.

The lens forming layer 35 includes a lens layer 34 and a light-transmitting layer 36.

The lens layer 34 is made of an inorganic material having a different refractive index from that of the light-transmitting layer 36, such as silicon oxynitride (SiON). The lens layer 34 includes a convex lens surface 34s protruding toward the pixel electrode 10 on its upper surface. The lens surface 34s is formed by etching the upper surface of the lens layer 34.

The light-transmitting layer 36 is formed at the lens layer 34. As with the light-transmitting layer 42, the light-transmitting layer 32 is made of an inorganic material such as silicon oxide. The light-transmitting layer 36 is formed by forming a silicon oxide film on the lens surface 34s and then flattening it by CMP or the like.

The light-transmitting layer 22 is provided on the light-transmitting layer 36.

The light-transmitting layer 22 is an optical path length adjusting layer and is made of an inorganic material such as silicon oxide as with the light-transmitting layer 42.

The protective layer 24 is provided on the light-transmitting layer 22. The protective layer 24 is made of, for example, an inorganic material having transmittancy and hygroscopicity, such as Borosilicate Glass (BSG).

The pixel electrode 10 is provided on the protective layer 24. The alignment film 12 is provided on the pixel electrode 10.

The pixel electrode 10 and the capacitive electrode 40 are electrically connected to each other via a contact plug 21, a relay layer 20, a contact plug 31, a relay layer 30, and a contact plug 41. In this manner, the pixel electrode 10 is electrically connected to the drain region 70d of the transistor 1 via the capacitive electrode 40. Also, in the embodiment, the relay layer 20 is an example of a first relay layer, the capacitive electrode 40 is an example of a second relay layer, and the relay layer 30 is an example of a third relay layer.

A contact hole 23 penetrating the light-transmitting layer 22 and the protective layer 24 is provided between the pixel electrode 10 and the relay layer 20.

The contact hole 23 is provided for electrically coupling the pixel electrode 10 to the relay layer 20. The contact plug 21 serving as a conductive member called a pixel contact plug is provided in the contact hole 23. The contact plug 21 is made of a light-shielding conductive material such as tungsten.

The relay layer 20 is provided between the light-transmitting layer 22 and the light-transmitting layer 36. The relay layer 20 is made of a material containing tungsten silicide (WSi) and/or titanium nitride (TiN).

The contact plug 31 is provided in a contact hole 33 penetrating the lens forming layer 35. Since the lens forming layer 35 is thicker than other interlayer insulating layers, the contact hole 33 has the highest aspect ratio among other contact holes.

The contact plug 31 electrically connects the relay layer 20 to the relay layer 30. The contact plug 31 is made of a light-shielding conductive material. In the embodiment, the contact plug 31 is made of tungsten or a conductive material containing tungsten.

Tungsten is more suitable for forming a contact plug having a fine structure with a high aspect ratio than other conductive materials. Accordingly, by using tungsten or a conductive material containing tungsten for the material of the contact plug 31, a difficulty level of forming the contact plug 31 can be lowered.

The relay layer 30 is provided between the light-transmitting layer 42 and the lens layer 34.

The relay layer 30 is made of a material containing titanium nitride.

A contact hole 43 penetrating the light-transmitting layer 42 is provided between the relay layer 30 and the capacitive electrode 40.

The contact hole 43 is provided for electrically coupling the relay layer 30 to the capacitive electrode 40, and the contact plug 41 serving as a conductive member is provided in the contact hole 43. The contact plug 41 is made of a light-shielding conductive material such as tungsten.

### 1.4. Planar Structure of Display Region of Element Substrate

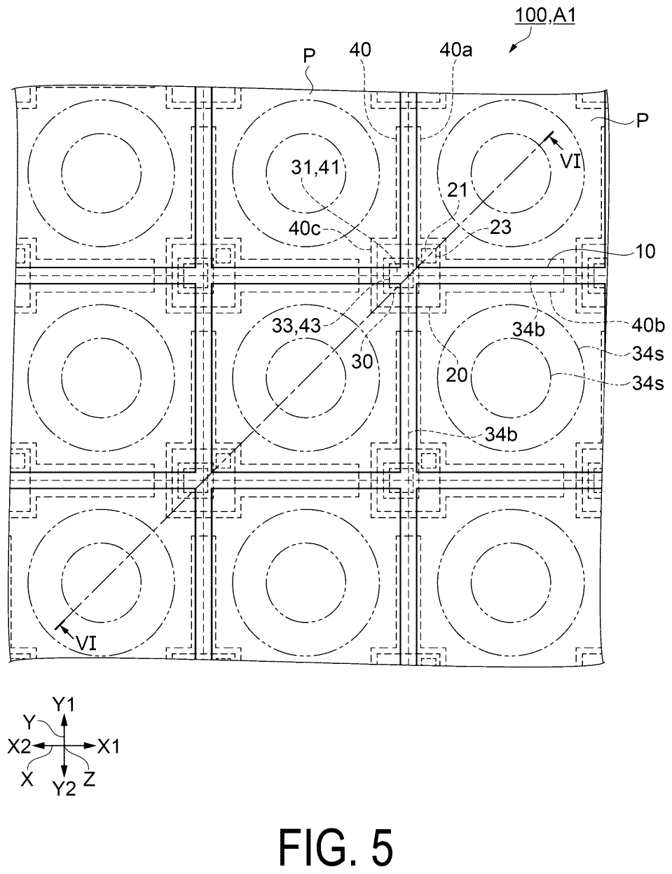

FIG. 5 is a plan view showing a part of the display region A1 of the element substrate 100 and shows a planar structure of the display region A1 when the display region A1 of the element substrate 100 is viewed from the liquid crystal layer Lc side in the Z2 direction in plan view.

In FIG. 5, an outer edge of the pixel electrode 10 is shown by a solid line, and outer edges of structures included in the optical functional layer LS among structures provided closer to the base material 90 than the pixel electrode 10 are shown by broken lines. In addition, a curved shape of the lens surface 34s is shown by a double circle with two-dot chain lines, and a boundary at which two adjacent lens surfaces 34s are adjacent to each other is shown by a boundary line 34b.

As shown in FIG. 5, the pixel electrode 10 has a predetermined size and a square shape. In addition, the pixel electrodes 10 are disposed in a matrix along the X axis and the Y axis at a predetermined pitch.

In the embodiment, the predetermined size of the pixel electrode 10 is about 6 μm in length and width, and the predetermined pitch is about 7 μm. Also, the above-described predetermined size and predetermined pitch of the pixel electrode 10 are merely examples and may be appropriately changed.

The lens surfaces 34s are provided for each pixel electrode 10. The lens surfaces 34s have a predetermined size and are provided at a predetermined pitch equal to or similar to that of the pixel electrodes 10.

A space between adjacent pixel electrodes 10 is a light-shielding region, and a center side of the pixel electrode 10 is a light-transmitting region through which light is transmitted. The light-transmitting region can be referred to as an aperture region. The contact plug 21, the contact plug 31, the relay layer 30, and the capacitive electrode 40 are provided in the light-shielding region. In addition, the transistor 1, the gate electrode 74, the scanning line 3, the data line 4, and the capacitance line 5, and the like, which are not shown in the figure, are provided in the light-shielding region. The contact plug 31, the relay layer 30, the capacitive electrode 40, the scanning line 3, the data line 4, and the capacitance line 5 provided in the light-shielding region are all provided to overlap the transistor 1 in plan view and function as a light-shielding layer of the transistor 1.

The contact plug 21 is provided at a position at which it overlaps the pixel electrode 10 and the relay layer 20, and in the embodiment, at a position at which it overlaps a lower left corner of the figure among four corners of the pixel electrode 10 and an upper right corner of the figured among four corners of the relay layer 20.

The contact hole 23 is provided at a position at which it does not overlap the contact hole 33 in plan view. When the contact hole 23 is provided at the position at which it does not overlap the contact hole 33 in this way, film formation of the pixel electrode 10 on the contact hole 23 can be improved as compared to when the contact hole 23 is provided at a position at which it overlaps the contact hole 33.

The contact hole 33 and the contact plug 31 are provided in a gap surrounded by corners of four adjacent pixel electrodes 10 in plan view.

A plurality of contact plugs 31 are disposed at a predetermined pitch. In the embodiment, the predetermined pitch is about 7 μm. Also, the predetermined pitch of the contact plugs 31 described above is an example and may be changed as appropriate.

The relay layer 30 is provided at a position at which it overlaps the relay layers 20 and 40, the contact holes 33 and 43, and the contact plugs 31 and 41 in plan view. The relay layer 30 has a predetermined size and a square shape.

In the embodiment, the size of the relay layer 30 is about 2 μm in length and width. The sizes of the relay layer 20 and the capacitive electrode 40 are both larger than that of the relay layer 30. Accordingly, the relay layer 30 is located inside outer edges of the relay layer 20 and the capacitive electrode 40 in plan view. In other words, the relay layer 30 is covered with the relay layer 20 in plan view from the pixel electrode 10 side, and the relay layer 30 is covered with the capacitive electrode 40 in plan view from the base material 90 side.

The contact plug 41 is provided at a position at which it overlaps the contact hole 33 and the contact plug 31.

The capacitive electrode 40 is provided at a position at which it overlaps the relay layers 20 and 30, the contact holes 23, 33, and 43, and the contact plugs 21, 31, and 41 in plan view.

The capacitive electrode 40 includes a wide portion 40c, a protruding portion 40a protruding in the Y1 direction from the wide portion 40c, and a protruding portion 40b protruding in the X1 direction from the wide portion 40c.
in plan view, the wide portion 40c has a size and a shape that overlap the entire relay layer 30. Further, the wide portion 40c overlaps the transistor 1 (not shown) in plan view. Also, in the embodiment, the wide portion 40c is an example of a main body portion, the protruding portion 40a is an example of a first protruding portion, and the protruding portion 40b is an example of a second protruding portion.

In the embodiment, shapes of the contact hole 23, the contact hole 33, and the contact hole 43, and shapes of the contact plug 21, the contact plug 31, and the contact plug 41 are rectangular in plan view, but they are not limited thereto and may be circular, for example.

### 1.5. Cross-Sectional Structure of Optical Functional Layer of Display Region of Element Substrate

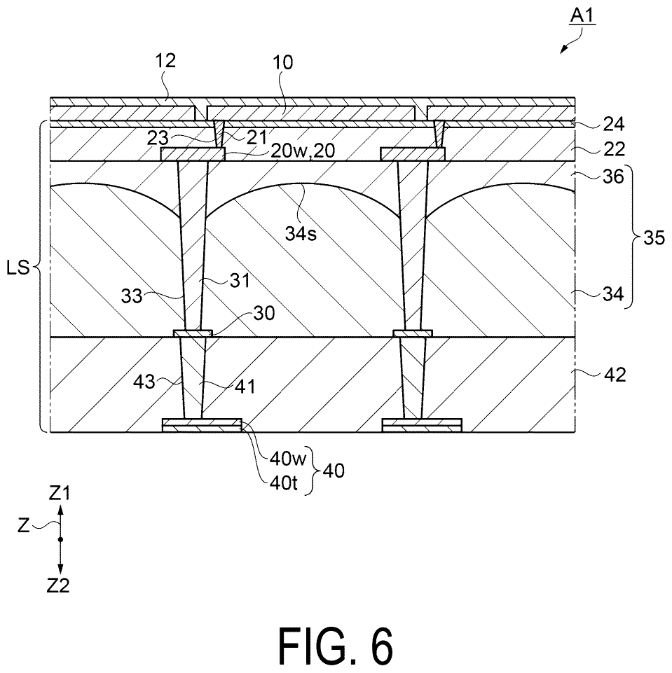

FIG. 6 is a cross-sectional view along line VI-VI in FIG. 5 and shows a cross-sectional structure of the optical functional layer LS.

In the embodiment, the relay layer 20 is configured of a single conductive layer including a WSi layer 20w containing WSi. A thickness of the WSi layer 20w is about 2000 Å.

The relay layer 30 is configured of a single conductive layer including a TiN layer containing titanium nitride.

The capacitive electrode 40 is configured of two conductive layers including a WSi layer 40w containing tungsten silicide and a TiN layer 40t containing titanium nitride.

The WSi layer 40w is provided on the light incidence side. A thickness of the WSi layer 40w is preferably set to 500 Å or more in order to exhibit light reflecting performance. For a thickness of the capacitive electrode 40, since a total thickness of the WSi layer 40w and the TiN layer 40t is about 2000 Å, a thickness of the TiN layer 40t is preferably set to 500 Å to 1500 Å depending on the thickness of the WSi layer 40w.

Here, a light absorption rate of TiN is about 75% for blue light (450 nm) and about 71% for green light (550 nm), and a light absorption rate of WSi is about 45% for both blue light and green light.

Accordingly, since the capacitive electrodes 40 have the WSi layer 40w on the light incidence side, even if some of the modulated light ML that have not been narrowed by the lens surface 34s hits the capacitive electrodes 40, the absorbed light can be reduced by about 30% as compared with a case in which the TiN layer 40t is on the light incidence side of the capacitive electrodes 40, and thus a temperature rise due to light absorption can be inhibited.

### 1.6. Modified Examples

The embodiment of the cross-sectional structure of the optical functional layer LS in the display region A1 of the element substrate 100 described above may be modified in various ways. Specific modified aspects will be exemplified below.

### 1.6.1. Modified Example 1

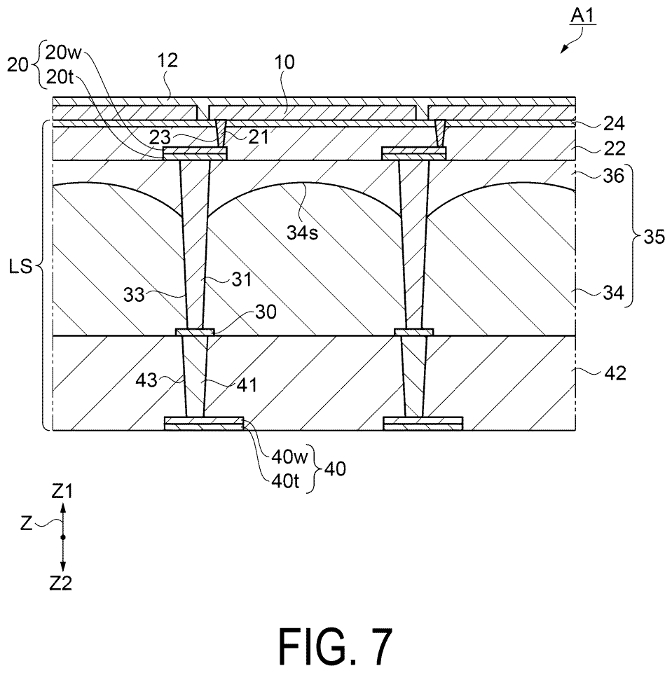

FIG. 7 is an explanatory diagram showing a cross-sectional structure of the optical functional layer LS according to Modified Example 1 and shows a modified example of the cross-sectional structure of the optical functional layer LS shown in FIG. 6.

In Modified Example 1, the relay layer 20 is configured of two conductive layers including the WSi layer 20w containing tungsten silicide and a TiN layer 20t containing titanium nitride.

The WSi layer 20w is provided on the light incidence side. A thickness of the WSi layer 20w is preferably set to 500 Å or more in order to exhibit light reflecting performance. Since a thickness of the relay layer 20 is about 2000 Å in total, a thickness of the TiN layer 20t is preferably set to 500 Å to 1500 Å depending on the thickness of the WSi layer 20w.

By providing the WSi layer 20w on the light incidence side of the TiN layer 20t, even if some of the modulated light ML that have passed through the liquid crystal layer Lc hits the relay layer 20, the absorbed light can be reduced by about 30% as compared to when the TiN layer 20t is on the light incidence side of the relay layer 20, and thus a temperature rise due to the light absorption can be inhibited.

In addition, by providing the TiN layer 20t on the contact plug 31 side, it is possible to increase contact resistance and adhesion with the contact plug 31 made of tungsten.

### 1.6.2. Modified Example 2

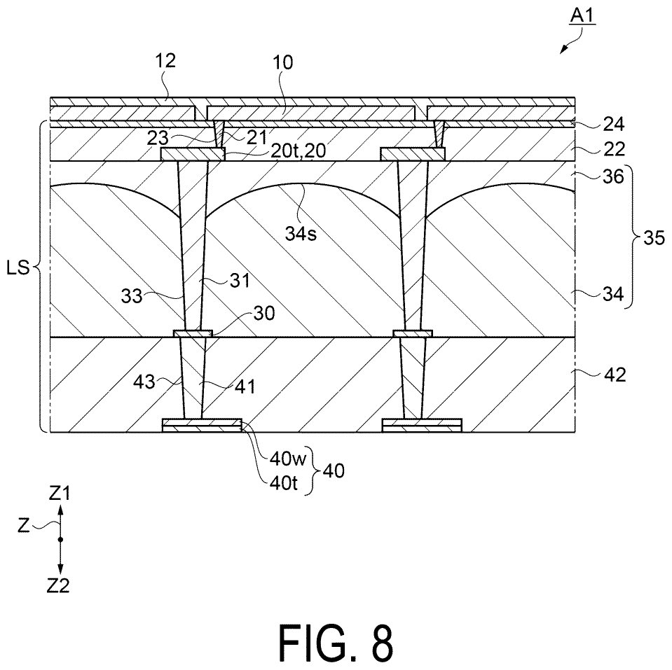

FIG. 8 is an explanatory diagram showing a cross-sectional structure of the optical functional layer LS according to Modified Example 2 and shows a modified example of the cross-sectional structure of the optical functional layer LS shown in FIG. 6.

In the Modified Example 2, the relay layer 20 is configured a single conductive layer including the TiN layer 20t. Accordingly, when the contact plug 21 is made of tungsten, contact resistance and adhesion with the contact plug 21 can be increased.

### 1.6.3. Modified Example 3

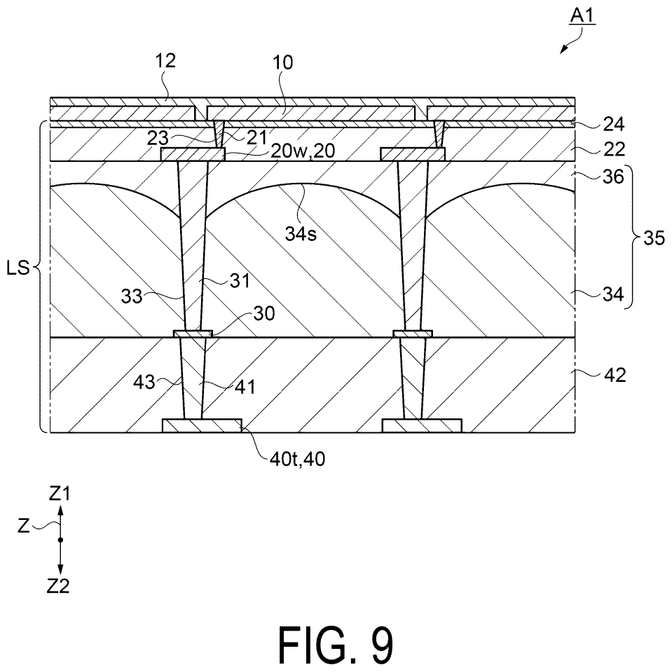

FIG. 9 is an explanatory diagram showing a cross-sectional structure of the optical functional layer LS according to Modified Example 3 and shows a modified example of the cross-sectional structure of the optical functional layer LS shown in FIG. 6.

In Modified Example 3, the relay layer 20 is configured of a single conductive layer including the WSi layer 20w, and the capacitive electrode 40 is configured of a single conductive layer including the TiN layer 40t. Thicknesses of each of the WSi layer 20w and the TiN layer 40t are about 2000 Å.

### 1.6.4. Modified Example 4

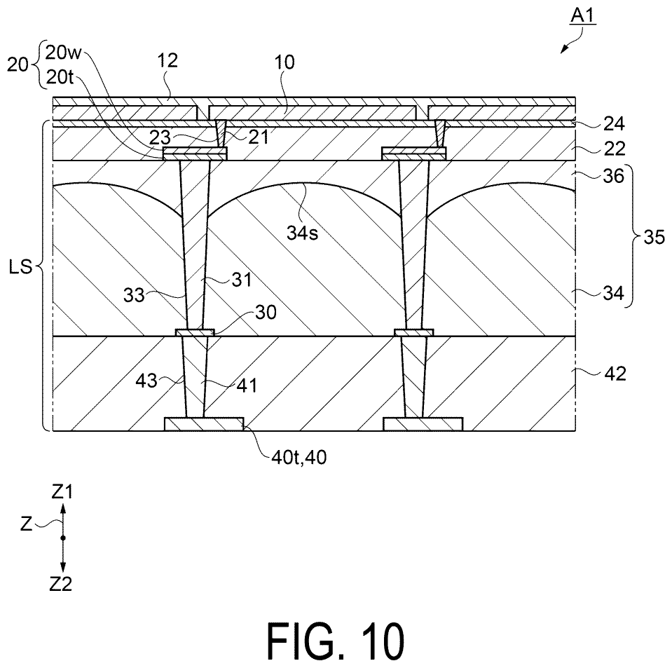

FIG. 10 is an explanatory diagram showing a cross-sectional structure of the optical functional layer LS according to Modified Example 4 and shows a modified example of the cross-sectional structure of the optical functional layer LS shown in FIG. 6.

In Modified Example 4, the relay layer 20 is configured of two conductive layers including the WSi layer 20w and the TiN layer 20t. The capacitive electrode 40 is configured of a single conductive layer including the TiN layer 40t.

As described above, according to the liquid crystal device 300 serving as the electro-optical device of the embodiment, the following effects can be obtained.

The liquid crystal device 300 according to the embodiment includes the transistor 1, the pixel electrode 10 provided on the light incidence side of the transistor 1, the lens layer 34 provided in a layer between the transistor 1 and the pixel electrode 10, and the relay layer 20 serving as the first relay layer that is provided in a layer between the lens layer 34 and the pixel electrode 10 and electrically connected to the pixel electrode 10, and the relay layer 20 includes WSi.

In this way, since the relay layer 20 includes the WSi layer 20w containing WSi on the pixel electrode 10 side, even if light hits the relay layer 20. The WSi layer can inhibit light absorption.

Accordingly, it is possible to inhibit an increase in the temperature of the liquid crystal device 300 including the liquid crystal layer Lc. Accordingly, generation of stains and deterioration in light resistance are inhibited, and a product life of the liquid crystal device 300 can be extended.

The liquid crystal device 300 according to the embodiment further includes the data line 4 extending in the Y1 direction serving as the first direction, the scanning line 3 extending in the X1 direction intersecting the Y1 direction serving as the second direction, and the capacitive electrodes 40 serving as the second relay layer that is provided in a layer between the transistor 1 and the lens layer 34 and electrically connected to the relay layer 20, the capacitive electrode 40 includes the wide portion 40c serving as the main body portion overlapping the transistor 1 in plan view, the protruding portion 40a serving as the first protruding portion protruding from the wide portion 40c in the Y1 direction, and the protruding portion 40b serving as the second protruding portion protruding from the wide portion 40c in the X1 direction, and the wide portion 40c, the protruding portion 40a, and the protruding portion 40b include WSi on the pixel electrode 10 side.

In this way, the capacitive electrode 40 includes the wide portion 40c, the protruding portion 40a, and the protruding portion 40b, and the wide portion 40c, the protruding portion 40a, and the protruding portion 40b include the WSi layer 40w containing WSi on the pixel electrode 10 side.

Accordingly, even if some of the modulated light ML that have not been narrowed by the lens layer 34 hits the capacitive electrode 40, the WSi layer 40w can inhibit light absorption, and a temperature rise due to the light absorption can be inhibited.

In the liquid crystal device 300 according to the embodiment, the protruding portion 40a serving as the first protruding portion protrudes from the relay layer 20 serving as the first relay layer in the Y1 direction serving as the first direction in plan view, and the protruding portion 40b serving as the second protruding portion protrudes from the relay layer 20 in the X1 direction serving as the second direction in plan view.

Accordingly, even if the protruding portion 40a and the protruding portion 40b are hit by light, they can inhibit absorbed light, and thus a temperature rise due to the light absorption can be inhibited.

The liquid crystal device 300 according to the embodiment further includes the light-transmitting layer 42 provided between the capacitive electrode 40 serving as the second relay layer and the lens layer 34, and the relay layer 30 serving as the third relay layer provided inside the outer edge of the first relay layer in plan view from the light incidence side, and the relay layer 30 includes TiN.

In this way, since the relay layer 30 is provided at a position covered with the relay layer 20 in plan view from the light incidence side, it is possible to inhibit the light from hitting the relay layer 30.

Accordingly, it is possible to inhibit an increase in the temperature of the liquid crystal device 300 including the liquid crystal layer Lc due to the light hitting the relay layer 30 including TiN having a higher light absorption rate than WSi.

The liquid crystal device 300 according to the embodiment includes the data line 4 extending in the Y1 direction serving as the first direction, the scanning line 3 extending in the X1 direction serving as the second direction intersecting the Y1 direction, the transistor 1 electrically connected to the data line 4 and the scanning line 3, the pixel electrode 10 provided on the light incidence side of the transistor 1, the lens layer 34 provided in a layer between the transistor 1 and the pixel electrode 10, the relay layer 20 serving as the first relay layer that is provided in a layer between the lens layer 34 and the pixel electrode 10 and electrically connected to the pixel electrode 10, and the capacitive electrode 40 serving as the second relay layer that is provided in a layer between the transistor 1 and the lens layer 34 and electrically connected to the relay layer 20, the capacitive electrode 40 includes the wide portion 40c serving as the main body portion overlapping the transistor 1 in plan view, the protruding portion 40a serving as the first protruding portion protruding from the wide portion 40c in the Y1 direction, and the protruding portion 40b serving as the second protruding portion protruding from the wide portion 40c in the X1 direction, and the wide portion 40c, the protruding portion 40a, and the protruding portion 40b include WSi on the pixel electrode 10 side.

In this way, the capacitive electrode 40 includes the wide portion 40c, the protruding portion 40a, and the protruding portion 40b, and the wide portion 40c, the protruding portion 40a, and the protruding portion 40b include the WSi layer 40w containing WSi on the pixel electrode 10 side, and thus even if some of the modulated light ML that have not been narrowed by the lens layer 34 hits the capacitive electrode 40, the WSi layer 40w can inhibit light absorption.

Accordingly, it is possible to inhibit an increase in the temperature of the liquid crystal device 300 including the liquid crystal layer Lc. Thus, generation of stains and deterioration in light resistance are inhibited, and the product life of the liquid crystal device 300 can be extended.

### 2. Embodiment 2

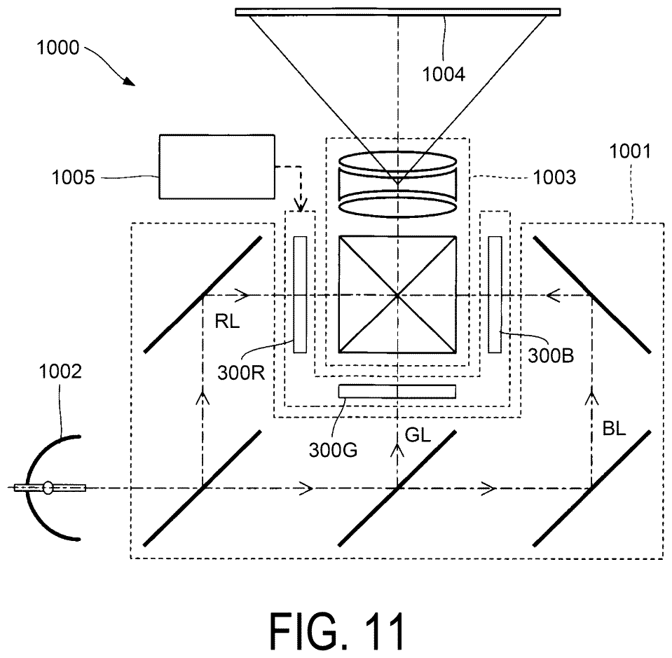

FIG. 11 is a schematic diagram showing an example of an electronic device and is a schematic diagram showing a schematic configuration of a projection type display device 1000 serving as the electronic device.

The projection type display device 1000 is, for example, a three-panel projector including three liquid crystal devices 300 described above. A liquid crystal device 300R corresponds to a red display color, a liquid crystal device 300G corresponds to a green display color, and a liquid crystal device 300B corresponds to a blue display color. A control unit 1005 includes, for example, a processor and a memory, and controls operations of the liquid crystal devices 300R, 300G, and 300B.

An illumination optical system 1001 supplies a red component RL of light emitted from an illumination device 1002, which is a light source, to the liquid crystal device 300R, supplies a green component GL to the liquid crystal device 300G, and a blue component BL to the liquid crystal device 300B. Each of the liquid crystal devices 300R, 300G, and 300B functions as a light modulation device that modulates each color light RL, GL, and BL supplied from the illumination optical system 1001 in accordance with a displayed image.

A projection optical system 1003 combines the light emitted from each of the liquid crystal devices 300R, 300G, and 300B and projects it on a screen 1004.

As described above, the projection type display device 1000 serving as the electronic device of the embodiment includes the liquid crystal device 300 described above.

Thus, by adopting the liquid crystal device 300 having high electrical reliability, the performance of the projection type display device 1000 can be improved.

Also, the electronic device is not limited to the exemplified three-panel projector. For example, the projector may be a single-panel type, a two-panel type, or a projector equipped with four or more liquid crystal devices 300. In addition, the electronic device may be a smartphone, a personal digital assistant (PDA), a camera, a television, a car navigation device, a personal computer, a display, an electronic paper, a calculator, a videophone, a point of sale (POS), a printer, a scanner, a copier, a video player, or a device equipped with a touch panel, or the like.

Although the preferred embodiments have been described above, the present disclosure is not limited to the above-described embodiments. In addition, the configuration of each unit of the present disclosure can be replaced with any configuration that exhibits the same function as in the above-described embodiments, or any configuration can be added.

What is claimed is:

1. An electro-optical device comprising:
a transistor;
a pixel electrode provided on a light incidence side of the transistor;
a lens layer provided in a layer between the transistor and the pixel electrode; and
a first relay layer that is provided in a layer between the lens layer and the pixel electrode and electrically connected to the pixel electrode, wherein
the first relay layer includes WSi.

2. The electro-optical device according to claim 1, further comprising:
a data line extending in a first direction;
a scanning line extending in a second direction intersecting the first direction; and
a second relay layer that is provided in a layer between the transistor and the lens layer and electrically connected to the first relay layer, wherein
the second relay layer includes a main body portion overlapping the transistor in plan view, a first protruding portion protruding from the main body portion in the first direction, and a second protruding portion protruding from the main body portion in the second direction, and
the main body portion, the first protruding portion, and the second protruding portion include WSi.

3. The electro-optical device according to claim 2, wherein
the first protruding portion protrudes from the first relay layer in the first direction in plan view, and the second protruding portion protrudes from the first relay layer in the second direction in plan view.

4. The electro-optical device according to claim 2, further comprising:
a light-transmitting layer provided between the second relay layer and the lens layer; and
a third relay layer provided between the light-transmitting layer and the lens layer on an inner side of an outer edge of the first relay layer in plan view from the light incidence side, wherein
the third relay layer includes TiN.

5. An electro-optical device comprising:
a data line extending in a first direction;
a scanning line extending in a second direction intersecting the first direction;
a transistor electrically connected to the data line and the scanning line;
a pixel electrode provided on a light incidence side of the transistor;
a lens layer provided in a layer between the transistor and the pixel electrode;
a first relay layer that is provided in a layer between the lens layer and the pixel electrode and electrically connected to the pixel electrode; and
a second relay layer that is provided in a layer between the transistor and the lens layer and electrically connected to the first relay layer, wherein
the second relay layer includes a main body portion overlapping the transistor in plan view, a first protruding portion protruding from the main body portion in the first direction, and a second protruding portion protruding from the main body portion in the second direction, and
the main body portion, the first protruding portion, and the second protruding portion include WSi.

6. An electronic device comprising the electro-optical device according to claim 1.
